(19) United States
(12) Patent Application Publication
(10) Pub. No.: US 2026/0279730 A1
(43) Pub. Date: Sep. 17, 2026

(54) DUAL-CHAMBER POWER DELIVERY SYSTEM

(71) Applicant: Applied Materials, Inc., Santa Clara, CA (US)

(72) Inventors: Sunil KAPOOR, Santa Clara, CA (US); Kartik RAMASWAMY, San Jose, CA (US); John FORSTER, Santa Clara, CA (US)

(21) Appl. No.: 19/080,670

(22) Filed: Mar. 14, 2025

(51) Int. Cl. H01J 37/32

(52) U.S. Cl. CPC H01J 37/32174; H01J 37/32183

(57) ABSTRACT

Aspects provided herein generally include apparatus, plasma processing systems and methods for delivering power to multiple chambers. One example apparatus generally includes: a first generator; a first distribution circuit having an input coupled to an output of the first generator; a first filter coupled between a first output of the first distribution circuit and a first combination node; a second filter coupled between a second output of the first distribution circuit and a second combination node; a second generator; a second distribution circuit having an input coupled to an output of the second generator; a third filter coupled between a first output of the second distribution circuit and the first combination node; and a fourth filter coupled between a second output of the second distribution circuit and the second combination node.

### BACKGROUND

### Field

Aspects of the present disclosure generally relate to a system and methods used in semiconductor device manufacturing. More specifically, aspects of the present disclosure relate to a plasma processing system used to process a substrate.

### Description of the Related Art

Reliably producing high aspect ratio features and/or filling high aspect ratio features with a conductive material create significant technology challenges for the next generation of semiconductor devices. Processes used to form the next generation of semiconductor devices will typically include plasma assisted etching or deposition processes. In one example, a method of forming high aspect ratio features utilizes a plasma assisted etching process that can include a reactive ion etch (RIE) plasma process, to form high aspect ratio openings in a material layer, such as a dielectric layer, of a substrate. In a typical RIE plasma process, a plasma is formed in a processing chamber and ions from the plasma are accelerated towards a surface of a substrate to form openings in a material layer disposed beneath a mask layer formed on the surface of the substrate.

Processes used to form the next generation of semiconductor devices will also include physical vapor deposition (PVD), plasma enhanced atomic layer deposition (PEALD), or plasma enhanced chemical vapor deposition (PECVD) techniques to deposit thin films of various metals and metal alloys within the various high aspect ratio features. However, PEALD, PECVD and PVD deposition processes can cause damage to the underlying layers of the substrate, particularly when high-energy ions are used to enhance the deposition rate or when the substrate features are small and have high aspect ratios. This damage can lead to poor step coverage and other defects, which can compromise the performance and reliability of the device.

Typical plasma processes involve deposition and removal of material on a substrate. In commercial scale manufacturing, each substrate contains many semiconductor devices, and many substrates are required to achieve the required volumes of devices that are to be manufactured each hour of each day. The commercial viability of a semiconductor processing operation depends in large part upon within-substrate uniformity and substrate-to-substrate repeatability of the process conditions. Accordingly, efforts are made to ensure that each portion of a given substrate and each substrate processed are exposed to the same processing conditions. Variation in the plasma processing conditions usually causes variation in deposition and etch rates resulting in unacceptable variation in the overall process and manufactured product(s).

Therefore, there is a need for techniques and apparatus that minimize process variations within substrates processed within a process chamber and process variations found on substrates processed different process chambers.

### SUMMARY

Aspects provided herein generally include apparatus, plasma processing systems and methods for power delivery to multiple stations or chambers.

Certain aspects of the present disclosure are directed towards an apparatus for processing a substrate in a plasma processing system. The apparatus generally includes: a first generator; a first distribution circuit having an input coupled to an output of the first generator; a first filter coupled between a first output of the first distribution circuit and a first combination node; a second filter coupled between a second output of the first distribution circuit and a second combination node; a second generator; a second distribution circuit having an input coupled to an output of the second generator; a third filter coupled between a first output of the second distribution circuit and the first combination node; and a fourth filter coupled between a second output of the second distribution circuit and the second combination node.

Certain aspects of the present disclosure are directed towards an apparatus for processing a substrate in a plasma processing system. The apparatus generally includes: a first generator; a first inductive element and a second inductive element magnetically coupled with the first inductive element, wherein a node between the first inductive element and the second inductive element is coupled to an output of the first generator; a first filter coupled between a terminal of the first inductive element and a first output node; and a second filter coupled between a terminal of the second inductive element and a second output node.

Certain aspects of the present disclosure are directed toward a method for processing a substrate in a plasma processing system. The method generally includes: generating a first signal via a first generator; providing, via a first distribution circuit, a first portion of the first signal to a first combination node through a first filter and a second portion of the first signal to a second combination node through a second filter; generating a second signal via a second generator; providing, via a second distribution circuit, a first portion of the second signal to the first combination node through a third filter and a second portion of the second signal to the second combination node through a fourth filter.

### BRIEF DESCRIPTION OF THE DRAWINGS

So that the manner in which the above recited features of the present disclosure can be understood in detail, a more particular description of the disclosure, briefly summarized above, may be had by reference to aspects, some of which are illustrated in the appended drawings. It is to be noted, however, that the appended drawings illustrate only exemplary aspects and are therefore not to be considered limiting of its scope, and may admit to other equally effective aspects.

FIG. 1 is a schematic representation of a plasma processing system, in accordance with certain aspects of the present disclosure.

FIG. 2A illustrates an example multi-chamber system, in accordance with certain aspects of the present disclosure.

FIG. 2B illustrates an example multi-chamber system used to drive two chambers, in accordance with certain aspects of the present disclosure.

FIG. 3 illustrates an example multi-chamber system implemented with a tapped inductive element, in accordance with certain aspects of the present disclosure.

FIG. 4A illustrates an example multi-chamber system implemented with a tapped inductive element, in accordance with certain aspects of the present disclosure.

FIG. 4B illustrates an example power delivery system to provide power to different electrodes of a station, in accordance with certain aspects of the present disclosure

FIGS. 4C and 4D illustrate example power delivery systems used to deliver power to electrodes in different stations, in accordance with certain aspects of the present disclosure

FIG. 5 is a process flow diagram illustrating a method of plasma processing, in accordance with certain aspects of the present disclosure.

To facilitate understanding, identical reference numerals have been used, where possible, to designate identical elements that are common to the figures. It is contemplated that elements and features of one embodiment may be beneficially incorporated in other aspects without further recitation.

### DETAILED DESCRIPTION

Aspects of the present disclosure generally relate to a system used in a semiconductor device manufacturing process. More specifically, aspects provided herein generally include apparatus and methods for delivering power to multiple chambers that facilitate balancing of the power provided to the different chambers. For example, a balancing circuit may be implemented with mutually coupled windings or inductive elements. The balancing circuit may receive power from a generator and split the power for delivery to the different chambers via the balancing circuit. The mutual coupling of the inductive elements forces a balancing of power delivered to the chambers. In some aspects, multiple generators may be used to generate signals of different frequencies. The different signals may be combined at a combination node, providing a wideband signal to a chamber for substrate processing, as described in more detail herein.

### Plasma Processing System Examples

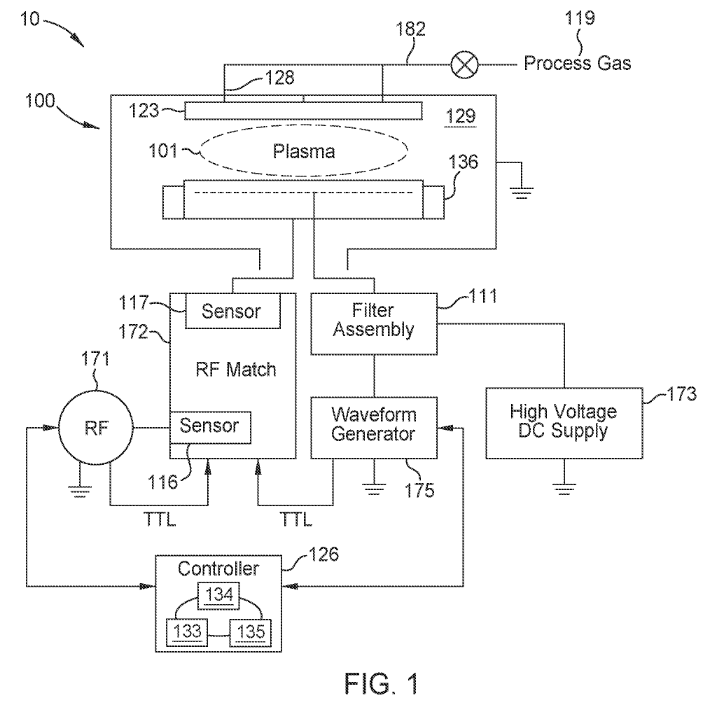

FIG. 1 is a schematic representation of a plasma processing system. The plasma processing system 10 is configured for plasma-assisted etching processes, such as a plasma-enhanced chemical vapor deposition (PECVD) chamber. The plasma processing system 10 can also be used in other plasma-assisted processes, such as reactive ion etch (RIE) plasma processes, or plasma-enhanced deposition processes (for example, plasma-enhanced chemical vapor deposition (PECVD) processes, plasma-enhanced physical vapor deposition (PEPVD) processes, plasma-enhanced atomic layer deposition (PEALD) processes, plasma treatment processing, plasma-based ion implant processing, or plasma doping (PLAD) processing. In one configuration, as shown in FIG. 1, the plasma processing system 10 is configured to form a capacitive coupled plasma (CCP). However, in some aspects, a plasma may alternately be generated by an inductively coupled plasma (ICP) source disposed over a processing region of the plasma processing system 10.

The plasma processing system 10 includes a processing chamber 100, a substrate support assembly 136, a gas delivery system 182, a high DC voltage supply 173, a radio frequency (RF) generator 171, and an RF match 172 (e.g., RF impedance matching network). A chamber lid 123 includes one or more sidewalls and a chamber base that are configured to withstand the pressures and energy applied to them while a plasma 101 is generated within a vacuum environment maintained in a processing volume 129 of the processing chamber 100 during processing.

The gas delivery system 182, which is coupled to the processing volume 129 of the processing chamber 100 is configured to deliver at least one processing gas from at least one gas processing source 119 to the processing volume 129 of the processing chamber 100. The gas delivery system 182 includes the processing gas source 119 and one or more gas inlets 128 positioned through the chamber lid 123. The gas inlets 128 are configured to deliver one or more processing gasses to the processing volume 129 of the processing chamber 100.

The processing chamber 100 includes an upper electrode (e.g., the chamber lid 123) and a lower electrode (e.g., the substrate support assembly 136) positioned in the processing volume 129 of the processing chamber 100. The upper and lower electrodes face one another. In one embodiment, the RF generator 171 is electrically coupled to the lower electrode. The RF generator 171 is configured to deliver an RF signal to ignite and maintain the plasma 101 between the upper and lower electrodes. In some alternative configurations, the RF generator 171 can also be electrically coupled to the upper electrode. For example, the RF generator 171 may deliver an RF source power to an RF baseplate within a cathode assembly (e.g., in the substrate support assembly 136) for plasma production, whereas the upper electrode is grounded. A center frequency of the RF source power can be from 13.56 MHz to very high frequency band such as 40 MHz, 60 MHz, 120 MHz or 162 MHz. In some examples, the RF source power can also be delivered through the upper electrode. The RF source power can be operated in a continuous mode or a pulsed mode. A pulsing frequency of the RF power can be from 100 to 10kHz, and duty cycles are ranging from 5% to 95%. The RF generator 171 has a frequency tuning capability and can adjust its RF power frequency within e.g., ±5% or ±10%. In some aspects, the RF generator 171 switches the RF power frequency at a predefined speed (e.g., two nanoseconds, fifty nanoseconds, etc.).

Referring to FIG. 1 the substrate support assembly 136 may be coupled to a high voltage DC supply 173 that supplies a chucking voltage thereto. The high voltage DC supply 173 may be coupled to a filter assembly 178 that is disposed between the high DC voltage supply 173 and the substrate support assembly 136.

The filter assembly 178 is configured to electronically isolate the high voltage DC supply 173 during plasma processing. In one configuration, a static DC voltage is between about -5000V and about 5000V, and is delivered using an electrical conductor (such as a coaxial power delivery line). The filter assembly 178 may include multiple filtering components or a single common filter.

The substrate support assembly 136 can include a pulsed voltage (PV) waveform generator 175 configured to supply a PV to bias an electrode 104 within the substrate support assembly 136. The PV waveform generator 175 is coupled to the filter assembly 178. The filter assembly 178 is disposed between the PV waveform generator 175 and the substrate support assembly 136. The filter assembly 178 is configured to electronically isolate the PV waveform generator 175 during plasma processing.

The substrate support assembly 136 can also include an RF generator 171 that is configured to deliver an RF signal to the processing volume 129 of the processing chamber 100. The RF generator 171 is electronically coupled to an RF matching circuit disposed between the RF generator 171 and the processing volume 129 of the processing chamber 100. For example, the RF matching circuit 172 is an electrical circuit used between the RF generator 171 and a plasma reactor (e.g., the processing volume 129 of the processing chamber 100) to optimize power delivery efficiency. One or more RF filters are designed to only allow RF waveforms in a selected RF frequency range to pass, and to isolate RF waveforms provide from other RF power supplies from each other. In some cases, a bandwidth of an RF filter has to be larger than a frequency tuning range of the RF generator 171.

During the plasma processing, the RF generator 171 delivers an RF signal to the substrate support assembly 136 via the RF matching circuit 172. For example, the RF signal is applied to a load (e.g., gas) in the processing volume 129 of the processing chamber 100. If an impedance of the load is not properly matched to an impedance of a source (e.g., the RF generator 171), a portion of a waveform can reflect back in an opposite direction. Accordingly, to prevent a substantial portion of the waveform from reflecting back, some implementations find a match impedance (e.g., a matching point) by adjusting one or more components of an RF matching circuit as the source and load impedances change. In some embodiments of the present disclosure, the RF power may be provided to the chamber load through one of multiple matching circuits set to respective impedances, allowing for a more rapid tuning of matching impedance as compared to adjusting an impedance of an RF matching circuit.

The RF generator 171 and the PV waveform generator 175 are each directly coupled to a system controller 126. The system controller 126 synchronizes the respective generated RF signal and PV waveform.

Voltage and current sensors can be placed at an input and/or output of the each RF matching circuit to measure impedance and other parameters. These sensors can be synchronized using an external transistor-transistor logic (TTL) synchronization signal from an advanced waveform generator and/or RF generators or using measured voltage and current data to determine timing internally. For example, an output sensor 117 is configured to measure the impedance of the plasma processing chamber 100, and other characteristics such as the voltage, current, harmonics, phase, and/or the like. An input sensor 116 is configured to measure the impedance of the RF generator 171 and other characteristics such as the voltage, current, harmonics, phase, and/or the like. Based on either of the synchronization signals or the characteristics of the plasma processing chamber 100, an RF matching circuit may be able to capture fast impedance changes and optimize impedance matching.

The PV waveform generator 175 is used to supply a PV waveform and/or a tailored voltage waveform, which is a sum of harmonic frequencies associated with the waveform. The PV waveform generator 175 may output a synchronization TTL signal to each RF matching circuit. The voltage waveform is coupled to a bias electrode (e.g., a bias electrode) through the filter assembly 178. The high DC voltage supply 173 is applied to chuck a substrate during a process for thermal control of the substrate. In some cases, there can be a third electrode at an edge of the cathode assembly for edge uniformity control.

The system controller 126, also referred to herein as a processing chamber controller, includes a central processing unit (CPU) 133, a memory 134, and support circuits 135. The system controller 126 is used to control a process sequence used to process the substrate 103. The CPU is a computer processor configured for use in an industrial setting for controlling the processing chamber and sub-processors related thereto. The memory 134 described herein, which is generally non-volatile memory, can include random access memory, read-inly memory, hard disk drive, or other suitable forms of digital storage, local or remote. The support circuits 135 are coupled to the CPU 133 and include cache, clock circuits, input/output subsystems, power supplied, and the like, and combinations thereof. Software instructions (program) and data can be coded and stored within the memory 134 for instructing a processor within the CPU 133. A software program (or computer instructions) readable by the CPU 133 in the system controller 126 determines which tasks are performable by the components in the plasma processing system 10.

The program, which is readable by the CPU 133 in the system controller 126 includes code, which, when executed by the CPU 133, performs tasks relating to the plasma processing schemes described herein. The program may include instructions that are used to control the various hardware and electrical components within the plasma processing system 10 to perform the various process tasks and various process sequences used to implement the methods described herein. The program includes instructions that are used to perform one or more of the operations described herein.

### Example Multi-Chamber System

Some processing systems may be implemented with dedicated generator systems. That is, each chamber or station may be implemented with a dedicated generator and automatch circuit. Dedicated generator systems that are provided to each plasma processing chamber within a multi-chamber plasma processing system incurs a large capital cost. Certain aspects of the present disclosure are directed towards a multi-chamber system that facilitates the usage of a generator for substrate processing in multiple stations or chambers, reducing the cost of the radio frequency (RF) system. The multi-chamber system is configured to distribute RF power to multiple stations/chambers while automatically balancing the power distribution to the stations/chambers. The multi-chamber system can provide a ballasting effect to remove loading/unloading issues experienced when plasma processes are started and stopped at different times in the different stations/chambers found within the multi-chamber system. While the discussion below primarily references embodiments of the disclosure being used in systems that include multiple “chambers,” which each include isolated processing regions, aspects of the disclosure can also be used in system configurations that include multiple “stations,” which include a plurality of multiple processing areas that are all housed within a single process volume, without deviating from the basic scope of the disclosure provided herein. The multi-chamber system may be modular and can be extended to any number of stations/chambers, such as two or more plasma processing chambers, three or more plasma processing chambers, four or more plasma processing chambers, six or more plasma processing chambers, or eight or more plasma processing chambers, or even 10 or more plasma processing chambers. The power to be provided to the different stations or chambers may be split after the RF generator or after the RF match circuitry (making a common generator/generator-match system). The multi-chamber generator configuration disclosed herein may be more reliable and save tool area and inventory space versus conventional systems that include dedicated generators.

In some implementations, a Wilkinson power divider may be used to split the power to be provided to the different chambers. Sometimes, a 3dB power divider using a common multi-path splitter may be used. The multi-chamber system of the present disclosure may use a tap (e.g., center tap) of an inductor or transformer to split and distribute power by auto-balancing the power to be provided to the chambers. In this manner, a Wilkinson divider and balancing system, such as a 3dB power divider, may not be used, reducing costs and area.

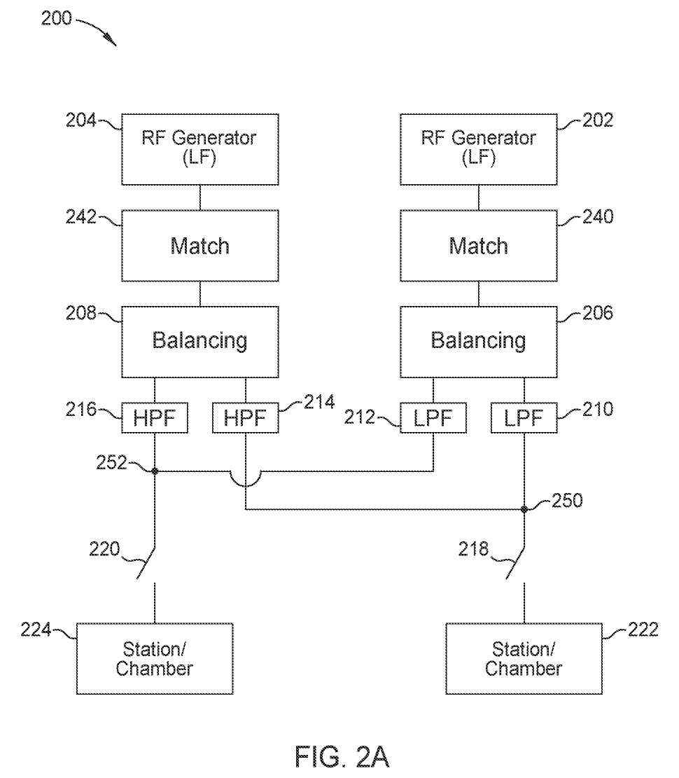

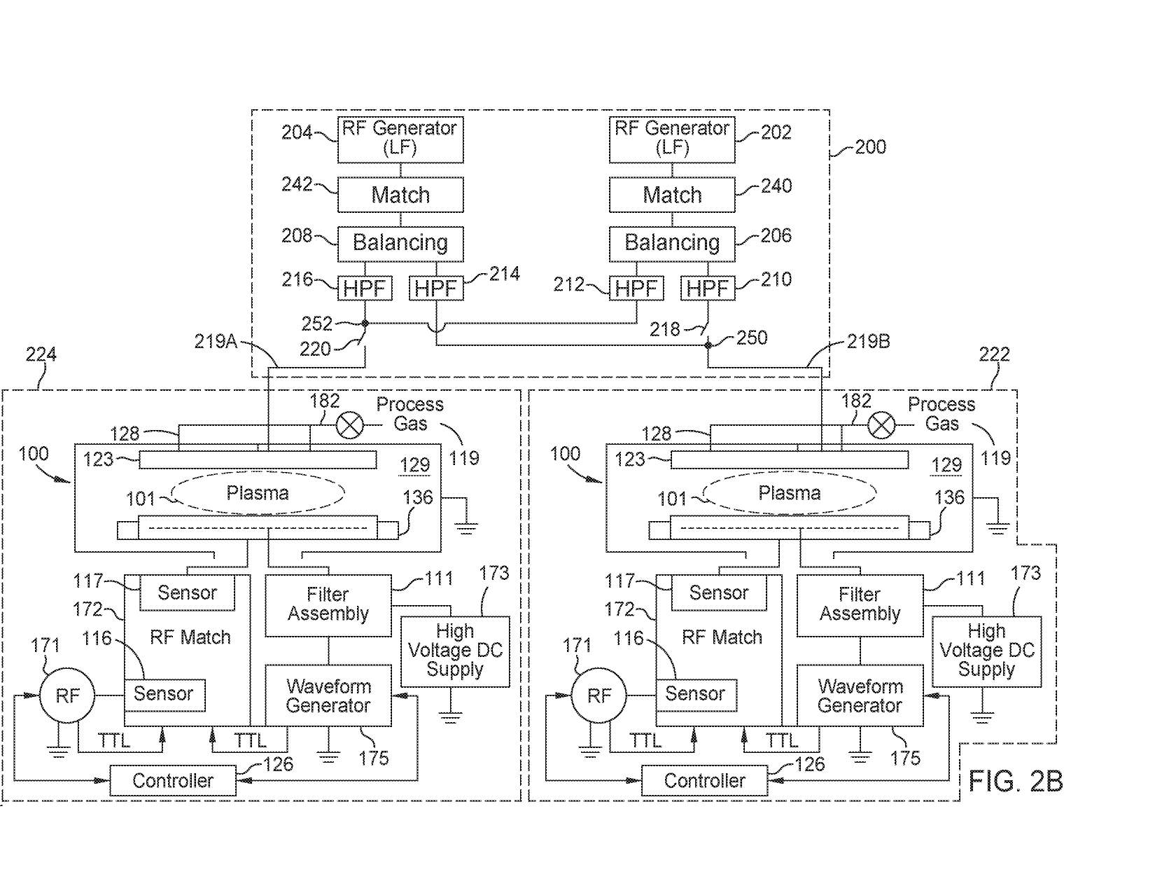

FIG. 2A illustrates an example multi-chamber system 200, in accordance with certain aspects of the present disclosure. As shown, the system 200 may include an RF generator 202 and an RF generator 204. The RF generator 202 may generate a low-frequency (LF) signal and the RF generator 204 may generate a high-frequency (HF) signal with a frequency higher than the LF signal. The LF signal may be provided to a match circuit 240 for impedance matching and the HF signal may be provided to a match circuit 242 for impedance matching. The signal from the match circuit 240 may be provided to a balancing circuit 206 that may split the signal from the match circuit 240 to be provided to different chambers 222, 224. In some aspects, the balancing circuit 206 may balance the power provided to the chambers 222, 224, as described in more detail herein. The different chambers 222, 224 may be used in different stations disposed within a processing chamber, in some cases. As shown, a first output of the balancing circuit 206 may be selectively coupled to the chamber 222 through a low-pass filter (LPF) 210 and a second output of the balancing circuit 206 may be selectively coupled to the chamber 224 through a LPF 212.

In a similar manner, the signal from the match circuit 242 may be provided to a balancing circuit 208 that may split the signal from the match circuit 242 to be provided to the different chambers 222, 224. In some aspects, the balancing circuit 206 may balance the power provided to the chambers 222, 224, as described in more detail herein. As shown, a first output of the balancing circuit 208 may be selectively coupled to the chamber 222 through a high-pass filter (HPF) 214 and a second output of the balancing circuit 208 may be selectively coupled to the chamber 224 through a HPF 216.

As shown, the first output of the balancing circuit 206 and the first output of the balancing circuit 208 may be coupled to a combination node 250 through the LPF 210 and the HPF 214, respectively. Similarly, the second output of the balancing circuit 206 and the second output of the balancing circuit 208 may be coupled to a combination node 252 through the LPF 212 and the HPF 216, respectively. The combination node 250 combines the HF and LF signals from the first outputs of the balancing circuits 206, 208, respectively, to generate a wideband signal to be provided to the chamber 222 through a switch 218. Similarly, the combination node 252 combines the HF and LF signals from the second outputs of the balancing circuits 206, 208, respectively, to generate a wideband signal to be provided to the chamber 224 through a switch 220. One or more of the switches 218, 220 may be closed to enable processing via one or more of the chambers 222, 224. If switch 218 or switch 220 is open, the connection to node 250 or node 252 may be opened. In some aspects, the chambers 222, 224 may be include different stations disposed within a processing chamber, as described herein.

The LPFs 210, 212 block (or at least attenuate) HF signals provided to the nodes 250, 252. Thus, LPFs 210, 212 prevent the flow of HF current from the RF generator 204 back to the RF generator 202, avoiding any damage to the RF generator 202. Similarly, HPFs 214, 216 block (or at least attenuate) LF signals provided to the nodes 250, 252. Thus, HPFs 214, 216 prevent the flow of LF current from the RF generator 202 back to the RF generator 204.

FIG. 2B illustrates the example multi-chamber system 200 used to drive two chambers, in accordance with certain aspects of the present disclosure. For example, the system 200 may drive chambers 222, 224 using respective transmission lines 219A, 219B. Each of the chambers 222, 224 may correspond to the plasma processing system 10 described with respect to FIG. 1.

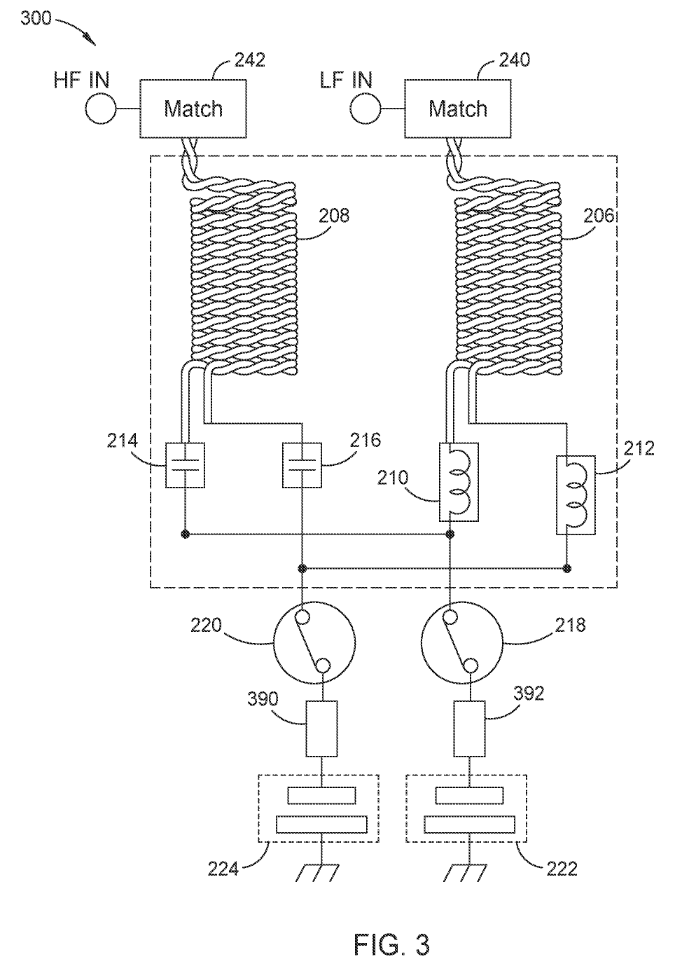

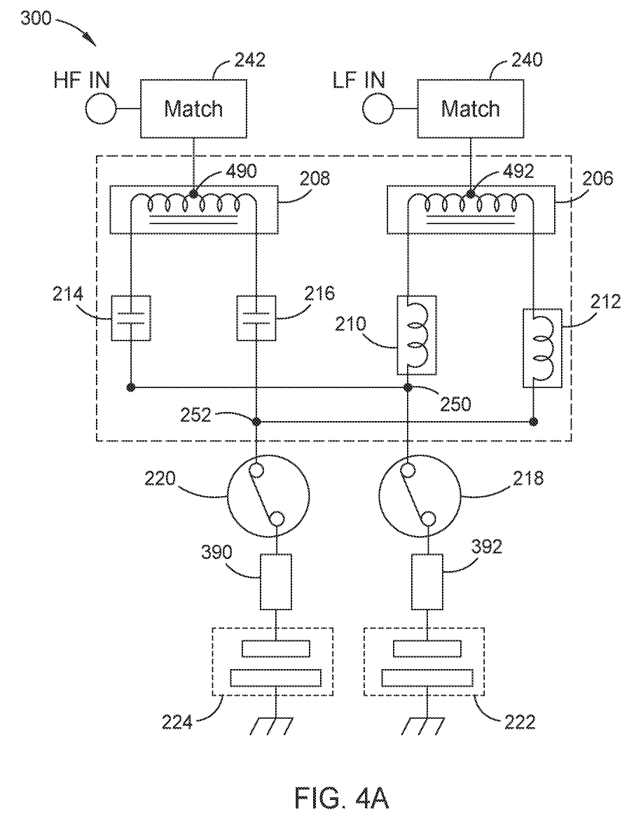

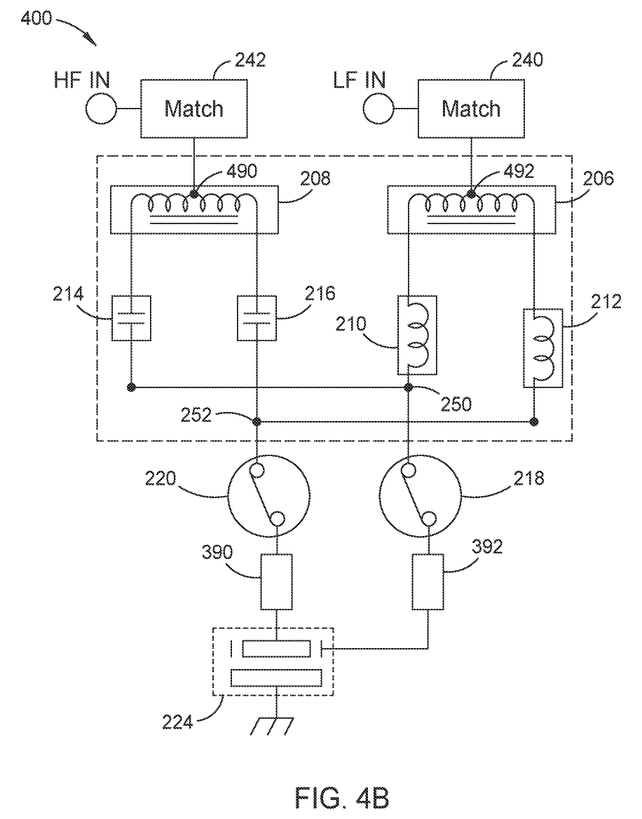

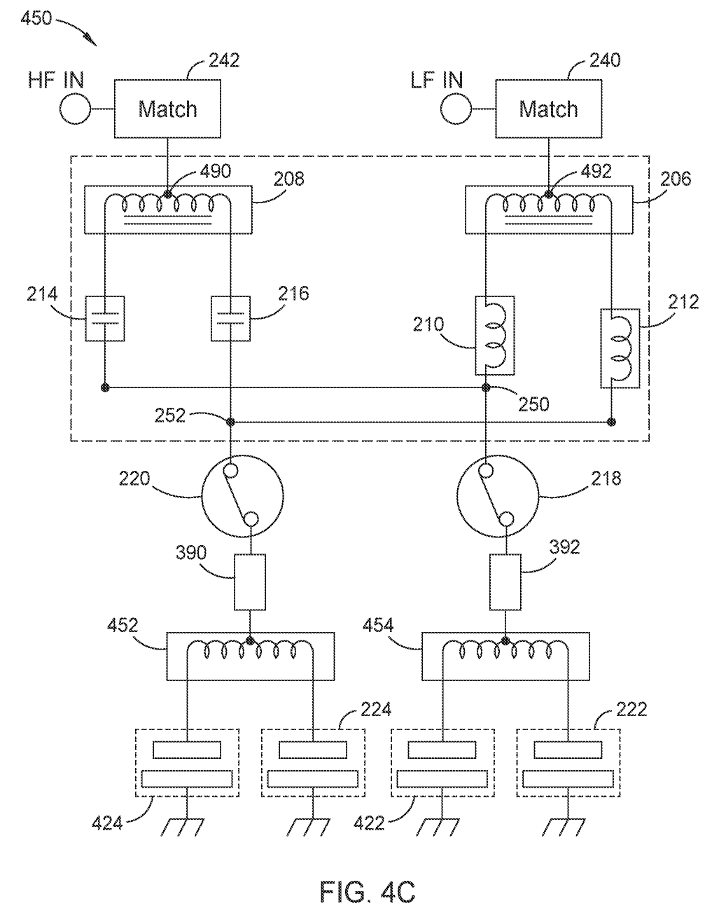

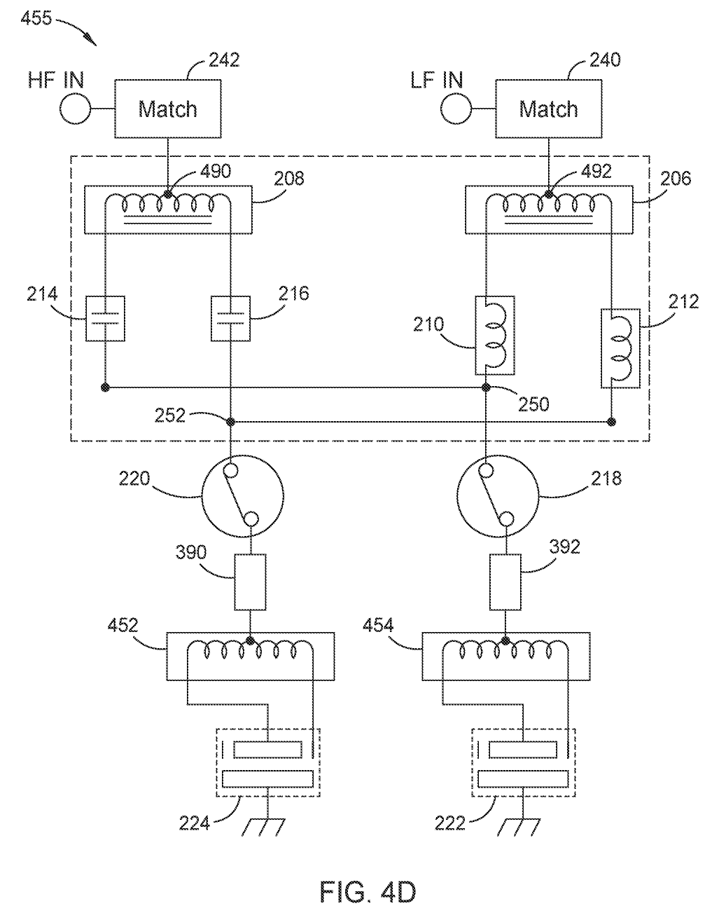

FIGS. 3 and 4A illustrate an example multi-chamber system 300, in accordance with certain aspects of the present disclosure. The balancing circuits 206, 208 may be implemented using mutually-coupled inductors, a center-tapped inductor, or a transformer. For example, the match circuit 242 may be coupled to a tap (e.g., at node 490) of a winding (e.g., inductive element) to form the balancing circuit 208, where a first portion of the winding between the tap and the filter 214 is magnetically coupled with a second portion of the winding between the tap and the filter 216. Similarly, the match circuit 240 may be coupled to a tap (e.g., at node 492) of a winding to form the balancing circuit 206, where a first portion of the winding between the tap and the filter 210 is magnetically coupled with a second portion of the winding between the tap and the filter 212. In this configuration, the magnetic coupling experienced between the windings is used to balance the RF power distribution provided by each RF generator 202, 204 automatically. The filters 214, 216 may be implemented using any suitable high-pass filter configuration. For example, the filters 214, 216 may be implemented with one or more fixed elements, such as a series capacitor, as described. The impedance of the fixed elements may be set to facilitate filtering of low-frequency signals (e.g., as opposed to other components that may have impedances set for impedance matching). Similarly, filters 210, 212 may be implemented using any suitable low-pass filter configuration. For example, the filters 210, 212 may be implemented with one or more fixed elements, such as a series inductor, as described. The impedance of the fixed elements may be set to facilitate filtering of high-frequency signals (e.g., as opposed to other components that may have impedances set for impedance matching).

As shown in FIGS. 3 and 4A, a match 390 may be coupled between the switch 220 and the chamber 224 and a match 392 may be coupled between the switch 218 and the chamber 222. The match 390 and match 392 may include a coaxial cable (e.g., where the length of the cable is set for impedance matching) or any suitable matching circuit.

The center-tapped inductor, transformer, or mutually-coupled inductors distribute and auto-balance power to the different chambers, as described herein. The mutual coupling between the winding or inductors (or portions of a center-tapped inductor or transformer) may force the RF driven electrode (e.g., showerhead) voltages of different chambers to be the same. For instance, assume that different chambers consume different amounts of RF power at the driven RF frequency. In this case, the chamber with the highest current (e.g., power draw) may force a high voltage across an associated inductor of the mutually coupled inductors. Due to the mutual coupling, the voltages across the inductors is forced to be the same, balancing the power provided to the chambers. Thus, due to the mutual coupling, the plasma in each chamber may be made to have a negligible difference, forcing a similar or same current to flow to each of the chambers. Thus, the mutual coupling provided by the center-tapped inductor, transformer, or mutually-coupled inductors results in the auto-balancing of the RF power provided to the chambers.

The multi-chamber system 300 provides cost and supporting component area reduction by reducing the number of RF components as compared to conventional implementations. The multi-chamber system 300 balances power distribution to chambers automatically, as described herein. The system also provides a ballasting effect to remove loading/unloading issues experienced when plasma processing is performed asynchronously. The system is also modular and can be extended to any number of stations or chambers. Power from each generator may be split directly from the output of the generator or after automatch is performed using a matching circuit as described. The multi-chamber system provides area savings and inventory reduction while also increasing reliability and lowering warranty and maintenance costs due to the usage of fewer components.

Beat frequency issues may not arise with the multi-chamber system configuration disclosed herein. In high-power and/or low-pressure processes, plasma from neighboring stations can become coupled, which affects the plasma process control if the stations are part of the same chamber. With the multi-chamber system described herein, plasma interference from neighboring stations may not occur as the stations may be part of different plasma processing chambers. Certain aspects also increase substrate processing tunability by providing independent control of each station and/or chamber at different RF frequencies.

FIG. 4B illustrates an example power delivery system 400 to provide power to different electrodes of a station, in accordance with certain aspects of the present disclosure. The power delivery system 400 may correspond to the multi-chamber system 300, but used to provide power to different electrodes within a station of a chamber. As shown, the power from node 252 may be selectively provided to a first electrode (e.g., showerhead) of the chamber 224 and the power from node 250 may be selectively provided to a second electrode (e.g., an edge electrode, which may surround the first electrode) of the chamber 224. In this manner, the power delivery system 400 provides power to multiple electrodes within a station for substrate processing.

FIGS. 4C and 4D illustrate an example power delivery systems 450, 455 used to deliver power to electrodes in different stations, in accordance with certain aspects of the present disclosure. As shown in FIG. 4C, a distribution circuit 452 (e.g., tapped inductor) may be coupled to the switch 220 to split the power from node 252 and provide power to showerheads of different stations or chambers 224, 424. Similarly, a distribution circuit 454 (e.g., tapped inductor) may be coupled to the switch 218 to split the power from node 250 and provide power to showerheads of different stations or chambers 222, 422. The distribution circuits 452, 454 may be implemented as inductors each having a tap. The position of the tap for each inductor may be adjustable to control the amount of power to be delivered to each electrode. For example, the tap of the inductor for the distribution circuit 452 may be moved closer to chamber 424 or closer to chamber 224 to increase (or decrease) the amount of power provided to chamber 224 and decrease (or increase) the amount of power provided to the chamber 424. As shown in FIG. 4D, the distribution circuit 452 may split the power from node 252 and provide power to different electrodes (e.g., showerhead and edge electrode) of a station or chamber 224. Similarly, the distribution circuit 454 may split the power from node 250 and provide power to different electrodes (e.g., showerhead and edge electrode) of a station or chamber 222. In some cases, the power may be split by each distribution circuit (e.g., each of distribution circuits 452, 454) and provided to electrodes of one or more stations within one or more chambers.

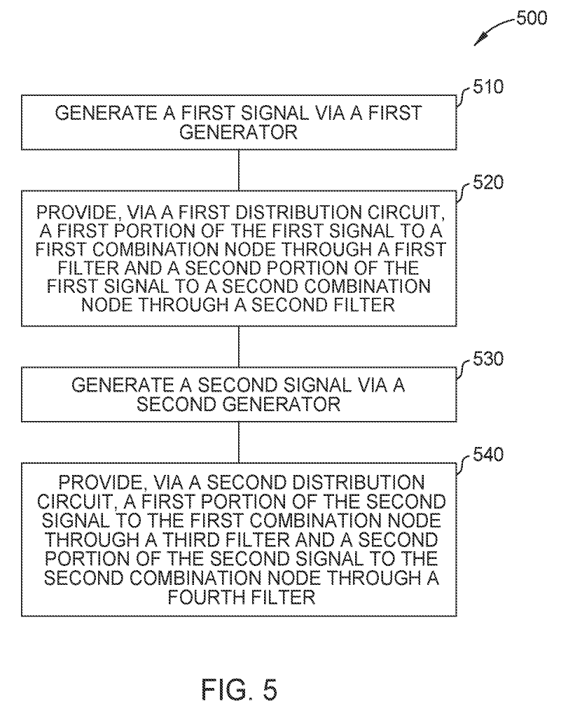

FIG. 5 is a process flow diagram illustrating a method 500 for processing a substrate, in accordance with certain aspects of the present disclosure. The method 500 can be performed by a plasma processing system, such as the multi-chamber system 200 or 300. The method 500 can also be performed by a plasma processing system that includes a plurality of processing stations within a processing chamber without deviating from the basic scope of the disclosure provided herein.

At operation 510, the plasma processing system may generate a first signal via a first generator (e.g., generator 202). At operation 520, the plasma processing system provides, via a first distribution circuit (e.g., balancing circuit 206), a first portion of the first signal to a first combination node (e.g., combination node 250) through a first filter (e.g., filter 210) and a second portion of the first signal to a second combination node (e.g., combination node 252) through a second filter (e.g., filter 212).

At operation 530, the plasma processing system generates a second signal via a second generator (e.g., generator 204). At operation 540, the plasma processing system provides, via a second distribution circuit (e.g., balancing circuit 208), a first portion of the second signal to the first combination node through a third filter (e.g., filter 214) and a second portion of the second signal to the second combination node through a fourth filter (e.g., filter 216). In some aspects, the first combination node is selectively coupled to a first chamber and the second combination node is selectively coupled to a second chamber. The first chamber and the second chamber may be part of different chambers, in some implementations.

At least one of the first distribution circuit or the second distribution circuit may include a tapped transformer, as illustrated in FIG. 4. In some aspects, the first distribution circuit may include mutually-coupled inductors, as illustrated in FIG. 3. A node (e.g., node 492) between the mutually-coupled inductors may be coupled to the first generator. In some aspects, the first distribution circuit includes an inductor. A tap of the inductor may be coupled to the first generator. The tap may be a center tap of the inductor. The second distribution circuit may include another inductor, where a tap of the other inductor is coupled to the second generator.

In some aspects, the first generator may be configured to generate a low frequency signal and the second generator is configured to generate a high frequency signal. In some aspects, at least one of the first filter or the second filter comprises a low-pass filter (LPF) and at least one of the third filter and the fourth filter comprises a high-pass filter (HPF). The first filter and the second filter may be configured to block signals from the second generator from reaching the first generator and the third filter and the fourth filter are configured to block signals from the first generator from reaching the second generator.

While the foregoing is directed to aspects of the present disclosure, other and further aspects of the disclosure may be devised without departing from the basic scope thereof, and the scope thereof is determined by the claims that follow.

What is claimed is:

1. An apparatus for processing a substrate in a plasma processing system, comprising:
a first generator;
a first distribution circuit having an input coupled to an output of the first generator;
a first filter coupled between a first output of the first distribution circuit and a first combination node;
a second filter coupled between a second output of the first distribution circuit and a second combination node;
a second generator;
a second distribution circuit having an input coupled to an output of the second generator;
a third filter coupled between a first output of the second distribution circuit and the first combination node; and
a fourth filter coupled between a second output of the second distribution circuit and the second combination node.

2. The apparatus of claim 1, wherein:
the first distribution circuit comprises a first balancing circuit configured to balance an amount of power from the first generator provided to electrodes of at least one station; and
the second distribution circuit comprises a second balancing circuit configured to balance an amount of power from the second generator provided to the electrodes of the at least one station.

3. The apparatus of claim 1, wherein at least one of the first distribution circuit or the second distribution circuit comprises a tapped transformer.

4. The apparatus of claim 1, wherein the first distribution circuit comprises mutually-coupled inductors, wherein a node between the mutually-coupled inductors is coupled to the first generator.

5. The apparatus of claim 1, wherein the first distribution circuit comprises an inductor, wherein a tap of the inductor is coupled to the first generator.

6. The apparatus of claim 5, wherein the tap comprises a center tap of the inductor.

7. The apparatus of claim 1, wherein:
the first generator is configured to generate a first frequency signal; and
the second generator is configured to generate a second frequency signal, the second frequency signal having a higher frequency than the first frequency signal.

8. The apparatus of claim 1, wherein:
at least one of the first filter or the second filter comprises a low-pass filter (LPF); and
at least one of the third filter and the fourth filter comprises a high-pass filter (HPF).

9. The apparatus of claim 1, wherein:
the first filter and the second filter are configured to block signals from the second generator from reaching the first generator; and
the third filter and the fourth filter are configured to block signals from the first generator from reaching the second generator.

10. The apparatus of claim 1, wherein:
the first combination node is selectively coupled, via a first switch, to a first electrode disposed within a first chamber; and
the second combination node is selectively coupled, via a second switch, to a second electrode disposed within a second chamber.

11. An apparatus for processing a substrate in a plasma processing system, comprising:
a first generator;
a first inductive element and a second inductive element magnetically coupled with the first inductive element, wherein a node between the first inductive element and the second inductive element is coupled to an output of the first generator;
a first filter coupled between a terminal of the first inductive element and a first output node; and
a second filter coupled between a terminal of the second inductive element and a second output node.

12. The apparatus of claim 11, wherein the first inductive element and the second inductive element comprise different portions of an inductor.

13. The apparatus of claim 11, further comprising:
a second generator;
a third inductive element;
a fourth inductive element magnetically coupled with the third inductive element, wherein a node between the third inductive element and the fourth inductive element is coupled to an output of the second generator;
a third filter coupled between a terminal of the third inductive element and the first output node; and
a fourth filter coupled between a terminal of the fourth inductive element and the second output node.

14. The apparatus of claim 13, wherein:
the first generator is configured to generate a first frequency signal; and
the second generator is configured to generate a second frequency signal, the second frequency signal having a higher frequency than the first frequency signal.

15. The apparatus of claim 13, wherein:
the first filter and the second filter are configured to block signals from the second generator from reaching the first generator; and
the third filter and the fourth filter are configured to block signals from the first generator from reaching the second generator.

16. The apparatus of claim 13, wherein:
the first output node is selectively coupled to a first electrode disposed within at least one station; and
the second output node is selectively coupled to a second electrode disposed within the at least one station.

17. The apparatus of claim 16, wherein:
the at least one station includes a first station and a second station;
the first electrode is disposed within the first station; and
the second electrode is disposed within the second station.

18. The apparatus of claim 17, wherein the first station and the second station are within different chambers.

19. The apparatus of claim 16, wherein the at least one station comprises a station, wherein the first electrode and the second electrode are within the station.

20. A method for processing a substrate in a plasma processing system, comprising:
generating a first signal via a first generator;
providing, via a first distribution circuit, a first portion of the first signal to a first combination node through a first filter and a second portion of the first signal to a second combination node through a second filter;
generating a second signal via a second generator; and
providing, via a second distribution circuit, a first portion of the second signal to the first combination node through a third filter and a second portion of the second signal to the second combination node through a fourth filter.
